(19) United States
(12) Patent Application Publication
(10) Pub. No.: US 2004/0113648 A1
(43) Pub. Date: Jun. 17, 2004

(54) Method of exposing desired layers in a multi-layer semiconductor using focused ion beams for physical failure

(76) Inventors: Wen-Jyh Hung, Penghu (TW); Wen-Bing Lee, Hsinchu (TW)

Correspondence Address: Finnegan, Henderson, Farabow,, Garrett & Dunner, L.L.P., 1300 I Street, N.W., Washington, DC, 20005-3315, US

(21) Appl. No.: 10/318,224

(22) Filed: Dec. 13, 2002

(51) Int. Cl. G01R 31/26

(52) U.S. Cl. 324/765

(57) ABSTRACT

A method for defecting a defect in a semiconductor wafer or package including a plurality of dies that includes conducting an electrical failure analysis on the semiconductor wafer or package, identifying a defect in at least one of the plurality of dies, identifying a target layer for analysis in the at least one defective die, removing the at least one upper layer of the identified defective die by a focused ion beams apparatus, and exposing the entire area of the target layer for physical defect analysis.

### FIELD OF THE INVENTION

This invention pertains in general to failure analysis of a semiconductor device, and more particularly, to a method of exposing desired layers in a multi-layer semiconductor device.

### BACKGROUND OF THE INVENTION

In general failure analysis for a semiconductor integrated circuit (IC), techniques or tools such as scanning electron microscope (“SEM”) or focused ion beams (“FIB”) have long been developed for detecting defects occurred in the back-end, or latter parts, of the manufacturing process. These tools are used in both electrical and physical analyses and can ascertain the root cause of defects.

However, for defects incurred in the front-end of the manufacturing process, or the initial manufacturing steps, for example, gate oxide layer defects, the root cause of such defects is difficult to ascertain through physical analysis even though a failed IC is detectable by an electrical analysis. FIB and TEM (transmission electron microscope) have traditionally been used to check for gate oxide defects. In using these tools, however, only a vertical section of the gate oxide layer is checked, resulting in a low detection rate of defects. In addition, in deep sub-micron process technology, the gate oxide layer of an IC becomes thinner and more susceptible to damage. For example, a gate oxide layer may become damaged by plasma during the manufacturing process or an electrostatic discharge (ESD) event.

U.S. Pat. No. 5,935,870 to Lee, entitled “Top View TEM Sample Preparation Method,” discloses a physical failure analysis that exposes a gate oxide layer in an IC. Lee describes a method that uses chemical mechanical polishing, etching, and ion milling to de-layer the layers overlying the gate oxide layer. This method, however, may be laborious and costly.

### SUMMARY OF THE INVENTION

In accordance with the invention, there is provided a method of exposing a target layer in a multi-layer semiconductor device having at least one upper layer overlapping the target layer. The method includes removing the at least one upper layer by a focused ion beams apparatus, and exposing an entire area of the target layer.

Also in accordance with the present invention, there is provided a method for preparing a semiconductor device for transmission electron microscope analysis that includes providing a multi-layer semiconductor device having at least one upper layer overlapping a target layer, and removing the at least one upper layer by an FIB so as to expose the full area of the target layer.

In accordance with the present invention, there is also provided a method for defecting a defect in a semiconductor wafer or package including a plurality of dies that includes conducting an electrical failure analysis on the wafer or package, identifying a defect in at least one of the plurality of dies, identifying a target layer for analysis in the at least one defective die, removing the at least one upper layer of the identified defective die by a focused ion beams apparatus, and exposing the entire area of the target layer for physical defect analysis.

Additional objects and advantages of the invention will be set forth in part in the description which follows, and in part will be obvious from the description, or may be learned by practice of the invention. The objects and advantages of the invention will be realized and attained by means of the elements and combinations particularly pointed out in the appended claims.

It is to be understood that both the foregoing general description and the following detailed description are exemplary and explanatory only and are not restrictive of the invention, as claimed.

The accompanying drawings, which are incorporated in and constitute a part of this specification, illustrate one embodiment of the invention and together with the description, serve to explain the principles of the invention.

### BRIEF DESCRIPTION OF THE DRAWINGS

FIG. 1 shows an exemplary conventional FIB structure;

FIG. 2 is a perspective view of a conventional multi-layer semiconductor device structure;

FIG. 3 is a perspective view of a sample de-layered semiconductor device consistent with one embodiment of the present invention; and

FIG. 4 is a flow chart of a method in accordance with one embodiment of the present invention.

### DESCRIPTION OF THE EMBODIMENTS

Reference will now be made in detail to the present embodiment of the invention, an example of which is illustrated in the accompanying drawings. Wherever possible, the same reference numbers will be used throughout the drawings to refer to the same or like parts.

In accordance with the present invention, there is provided a method to expose a target layer in a multi-layer semiconductor device by using a FIB to de- layer at least one upper layer overlapping the target layer.

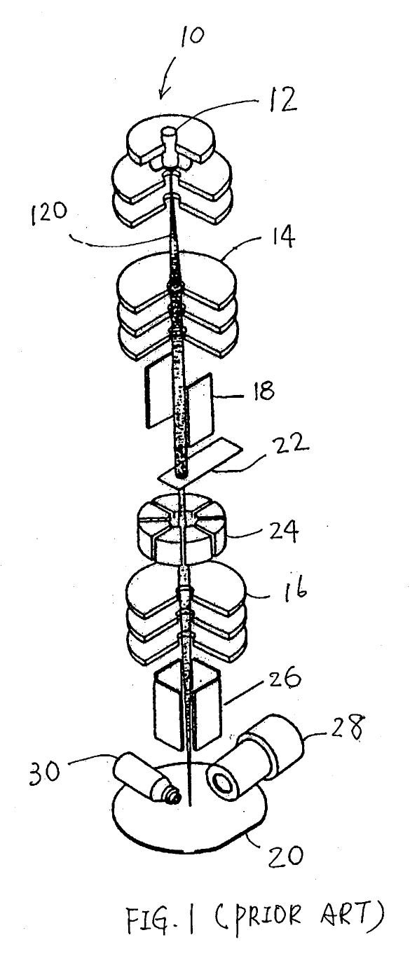

FIG. 1 shows an exemplary conventional focused ion beams (“FIB”) structure that may be used for purposes of the present invention. Referring to FIG. 1, a FIB structure 10 usually includes an ion source 12, for example, a Ga+ source, a condenser lens 14 together with an objective lens 16 for focusing an ion beam 120 through an ion focusing means 18 onto a sample 20, e.g., a semiconductor device, including a semiconductor wafer or package. FIB structure 10 usually also includes a selectable aperture 22, a blanker 24, a deflector 26, a detector 28, and a gas injector 30. Since FIB structure 10 is a conventional apparatus, functions of the above FIB elements are not further discussed.

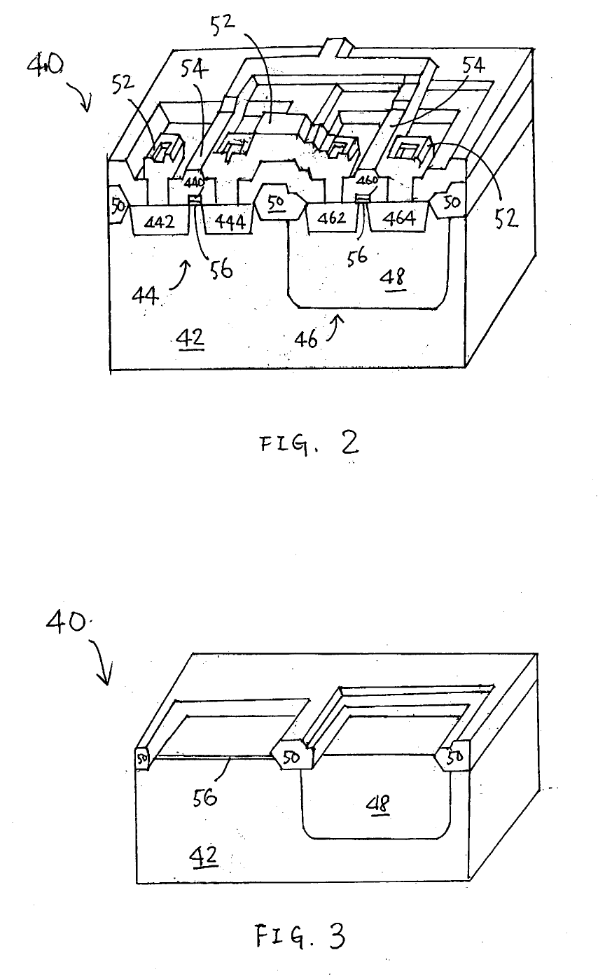

FIG. 2 shows a perspective view of a multi-layer device 40 to be analyzed by a TEM. Referring to FIG. 2, multi-layer device 40, e.g., a semiconductor device having multiple layers, includes a substrate 42, an NMOS transistor 44, a PMOS transistor 46 formed in an n-well 48, isolating structures 50, a metal layer 52 and a dielectric layer 54. NMOS transistor 44 includes a polysilicon gate 440 formed over a gate oxide layer 56, and diffused regions 442 and 444 coupled to metal layer 52. Similarly, PMOS transistor 46 includes a polysilicon gate 460 formed over gate oxide layer 56, and diffused regions 462 and 464 coupled to metal layer 52.

Metal layer 52 overlaps dielectric layer 54, that in turn overlaps polysilicon layer 440, that in turn overlap gate oxide layer 56. To expose gate oxide layer 56 of NMOS transistor 44, a FIB apparatus is directed upon multi-layer device 40 to remove the upper layers 52, 54 and 440 overlying gate oxide layer 56. In one embodiment, the full area of gate oxide layer 56 is expose to facilitate a subsequent TEM analysis.

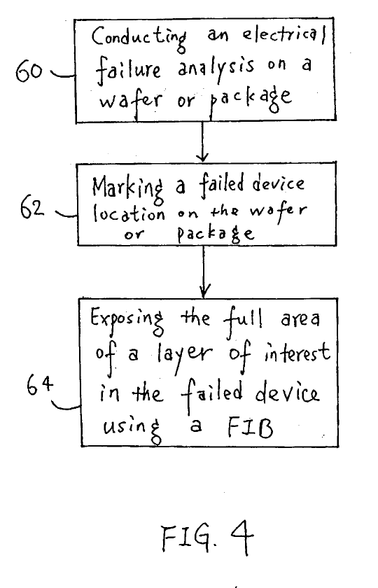

FIG. 3 shows multi-layer device 40 with gate oxide layer 56 fully exposed. Therefore, the present invention is able to provide a method to prepare a sample device suitable for TEM analysis after finishing the electrical analysis to define failure layers. With the entire area of the gate oxide layer 56 exposed, the defect detection rate is improved.

FIG. 4 is a flow chart of a method in accordance with the invention. Referring to FIG. 4, an electrical failure analysis is first conducted on a manufactured semiconductor wafer or package at step 60. The manufactured semiconductor wafer or package includes a plurality of dies. When the electrical failure analysis detects failure on one of the dies, the failed die is marked so as to be distinguished from non-defective dies at step 62. A FIB structure is directed at step 64 upon the failed device to expose a layer of interest, for example, a gate oxide layer. The FIB then removes the upper layers overlapping the layer of interest and exposes the entire area of the layer of interest so as to facilitate a subsequent TEM analysis. Therefore, the present invention also provides a method for physical analysis on device defects.

Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A method of exposing a target layer in a multi-layer semiconductor device having at least one upper layer overlapping the target layer, comprising:
removing the at least one upper layer by a focused ion beams apparatus; and
exposing an entire area of the target layer.

2. The method as claimed in claim 1, wherein the target layer is a gate oxide layer.

3. A method for preparing a semiconductor device for transmission electron microscope analysis, comprising:
providing a multi-layer semiconductor device having at least one upper layer overlapping a target layer; and
removing the at least one upper layer by an FIB so as to expose the full area of the target layer.

4. The method as claimed in claim 3, wherein the target layer is a gate oxide layer.

5. A method for defecting a defect in a semiconductor device including a plurality of dies, comprising:
conducting an electrical failure analysis on the semiconductor device;
identifying a defect in at least one of the plurality of dies;
identifying a target layer by electrical analysis in the at least one defective die;
removing the at least one upper layer of the identified defective die by a focused ion beams apparatus; and
exposing the entire area of the target layer for physical defect analysis.

6. The method as claimed in claim 5, wherein the target layer is a gate oxide layer.

7. The method as claimed in claim 5, wherein the semiconductor device is a wafer.

8. 8. The method as claimed in claim 5, wherein the semiconductor device is a package.
